(19) United States
(12) Patent Application Publication
(10) Pub. No.: US 2025/0132127 A1
(43) Pub. Date: Apr. 24, 2025

(54) TRANSFORMER COUPLED PLASMA SOURCE DESIGN FOR THIN DIELECTRIC FILM DEPOSITION

(71) Applicant: Lam Research Corporation, Fremont, CA (US)

(72) Inventors: Tongtong Guo, Beaverton, OR (US); Rachel E. Batzer, Tigard, OR (US); Lee Chen, Cedar Creek, TX (US); Francisco J. Juarez, West Linn, OR (US); Andrew John McKerrow, Lake Oswego, OR (US); Bo Gong, Sherwood, OR (US); Malak Khojasteh, Happy Valley, OR (US); Zhe Gui, Beaverton, OR (US); Huatan Qiu, Portland, OR (US)

(21) Appl. No.: 18/681,489

(22) PCT Filed: Aug. 5, 2022
(86) PCT No.: PCT/US2022/074608

§ 371 Date: Feb. 5, 2024

Related U.S. Application Data
(60) Provisional application No. 63/260,044, filed on Aug. 6, 2021.

(51) Int. Cl. H01J 37/32

(52) U.S. Cl. CPC H01J 37/3211; H01J 37/32119

(57) ABSTRACT

An apparatus, comprising: a process chamber, wherein the process chamber comprises: a window, wherein the window comprises a dielectric material that is transmissive to radio frequency (RF) energy, wherein the window has a first side and a second side opposite the first side; a collar assembly having an aperture covered by the window, wherein the collar assembly supports the first side of the window; and one or more RF coils positioned above the second side of the window, wherein, when viewed along a first axis perpendicular to the window, a radial distance between an outermost portion of the one or more RF coils and an innermost portion of an electrically conductive portion of the collar assembly that intersects with a first reference plane that is perpendicular to the first axis and between the first side of the window and the one or more RF coils is greater than or equal to 40 mm.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Plasma sources are used to create a plasma that, when a process gas is flowed into them, creates neutral particles, ions, and/or radicals of the process gas. These particles may then be flowed to react physically and/or chemically with a substrate of interest. An electric field may be used to generate the plasma, where the electric field is produced from one or more coils.

Background and contextual descriptions contained herein are provided solely for the purpose of generally presenting the context of the disclosure. Much of this disclosure presents work of the inventors, and simply because such work is described in the background section or presented as context elsewhere herein does not mean that it is admitted to be prior art.

### SUMMARY

Disclosed herein are systems and methods relating to the design and use of a radio frequency (RF) generator. In one aspect of the embodiments herein, an apparatus is provided, the apparatus including: a process chamber, wherein the process chamber includes: a window, wherein the window includes a dielectric material that is transmissive to radio frequency (RF) energy, wherein the window has a first side and a second side opposite the first side; a collar assembly defining an aperture covered by the window, wherein the collar assembly supports the first side of the window; and one or more RF coils positioned above the second side of the window, wherein, when viewed along a first axis perpendicular to the window, a radial distance between an outermost portion of the one or more RF coils and an innermost portion of an electrically conductive portion of the collar assembly that intersects with a first reference plane that is perpendicular to the first axis and between the first side of the window and the one or more RF coils is greater than or equal to 40 mm.

In some embodiments, the dielectric material has a dielectric constant less than 10. In some embodiments, the dielectric material is aluminum nitride, aluminum oxide, or both. In some embodiments, the one or more coils include 4 or fewer total turns. In some embodiments, the one or more coils include 3 or fewer total turns. In some embodiments, the diameter of the flat window is less than 350 mm. In some embodiments, further including a housing that is mechanically coupled to the collar assembly, wherein the one or more RF coils are within an interior volume of the housing. In some embodiments, the collar assembly includes an annular structure that is not circumferentially continuous. In some embodiments, the annular structure includes one or more gaps. In some embodiments, further including one or more cooling structures that direct air towards the flat window. In some embodiments, the window has a thickness between 20 mm and 25 mm. In some embodiments, the aperture has a diameter between 350 mm and 400 mm.

In some embodiments, further including one or more processors and one or more memories connected to the one or more processors, the one or more memories storing computer-executable instructions that, when executed by the one or more processors, control the one or more processors to: cause a first process gas including hydrogen gas to be flowed into a plasma volume below the window; and cause a plasma to be ignited using the first process gas, wherein the plasma is generated by providing power to the one or more RF coils. In some embodiments, the computer-executable instructions that, when executed by the one or more processors, control the one or more processors to cause the first process gas to be flowed into the plasma volume cause the first process gas to be flowed into the plasma volume without an accompanying flow of helium. In some embodiments, the plasma is an inductively coupled plasma. In some embodiments, the one or more memories store further computer-executable instructions that, when executed by the one or more processors, control the one or more processors to cause the plasma to transition to an inductively coupled plasma at a power of the one or more RF coils of less than 1000W. In some embodiments, the one or more memories store further computer executable instructions that, when executed by the one or more processors, control the one or more processors to cause the process chamber to maintain a pressure of the plasma volume greater than 1 Torr. In some embodiments, the one or more memories store further computer-executable instructions that, when executed by the one or more processors, control the one or more processors to cause the process chamber to maintain a pressure of the plasma volume between 1 Torr and 3 Torr. In some embodiments, the process chamber further includes a showerhead positioned below the window. In some embodiments, the process chamber further includes a pedestal configured to support a substrate.

These and other features of the disclosed embodiments will be described in detail below with reference to the associated drawings.

### BRIEF DESCRIPTION OF DRAWINGS

FIG. 1 presents a cross-sectional view of a plasma generator system according to various embodiments herein.

FIG. 2 presents a process flow for a method according to various embodiments herein.

FIG. 3 presents an enlarged view of a portion of the plasma generator system depicted in FIG. 1.

FIG. 4 is a top-down view of a portion of the plasma generator system depicted in FIG. 1.

FIG. 5 is an alternative coil design according to various embodiments herein.

### DETAILED DESCRIPTION

This disclosure relates to a process chamber having a radio frequency (RF) source for plasma processes. Plasma may be used in various processes for physically and/or chemically altering a surface of a workpiece. For example, plasma may be used to deposit or spray a layer of material onto a workpiece, to etch or sputter away unwanted material from a workpiece, or to perform ashing or stripping processes on a workpiece. Plasma may be generated by a plasma generator system. The plasma generator system may flow a process gas into a plasma volume that is subject to an electric field. The electric field may cause the process gas to dissociate into neutral particles, ions, and/or radicals, which may then be flowed to a workpiece to chemically and/or physically alter the workpiece.

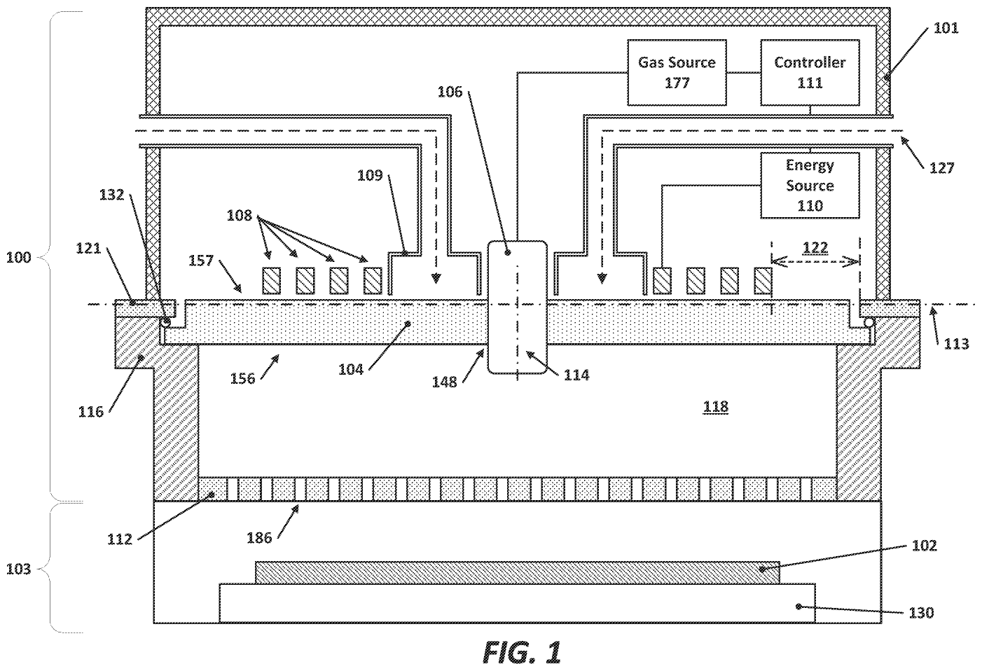

FIG. 1 is a simplified, cross-sectional view of a plasma generator system 100, according to an exemplary embodiment of the present invention. The plasma generator system 100 is configured to generate plasma, which may be used to deposit or remove material from a workpiece 102. For example, the plasma generator system 100 may be used in conjunction with systems or components used for various plasma processing techniques, such as plasma enhanced chemical vapor deposition, plasma etching, plasma stripping or ashing, sputtering, plasma spraying, and the like. Accordingly, the workpiece 102 may be a substrate that may be subjected to one or more of the aforementioned processes. For instance, the workpiece 102 may be made of relatively pure silicon, germanium, gallium arsenide, or other semiconductor material typically used in the semiconductor industry, or of silicon admixed with one or more additional elements such as germanium, carbon, and the like, in an embodiment. In another embodiment, the workpiece 102 may be a semiconductor substrate having layers that have been deposited thereover during a conventional semiconductor fabrication process. In still another embodiment, the workpiece 102 may be a component, such as a sheet of glass, ceramic or metal that may be subjected to plasma processing.

The plasma generator system 100 may be a remote apparatus or an in-situ module that is incorporated into a processing system, such as a process chamber. In accordance with an exemplary embodiment of the present invention, the plasma generator system 100 includes a housing 101, window 104, a coil 108, an energy source 110, a controller 111, a gas flow distributor 106, and a showerhead 112. In some embodiments, the plasma generator system 100 may be part of or connected to a process chamber 103, such that showerhead 112 distributes process gases toward substrate 102. In the embodiment shown in FIG. 1, substrate 102 is located beneath showerhead 112, and is shown resting on a movable pedestal 130. It will be appreciated that showerhead 112 may have any suitable shape, and may have any suitable number and arrangement of ports 186 for distributing processes gases to substrate 102. While FIG. 1 shows the showerhead 112 as part of the plasma generator system 100, in some embodiments the showerhead 112 may be part of the process chamber 103 or may be omitted, i.e. the substrate 102 is exposed to a plasma without a showerhead between the substrate 102 and the plasma.

The window 104, along with a collar assembly 116 and a showerhead 112, may define a plasma volume 118 that is configured to receive a processing gas that can be ionized by an electric field and transformed into a plasma, including species such as electrons, ions, and reactive radicals, for depositing material onto or removing material from the workpiece 102. In some embodiments the window 104 may have a first side 156 facing towards the plasma volume 118 and a second side 157 opposite the first side 156 and facing towards the coils 108. In this regard, the window 104 is made of a material that is capable of transmitting an electric field. In accordance with an exemplary embodiment, the window 104 may comprise one or more materials including the aforementioned properties. For example, the window 104 may be made of an insulating material, such as a dielectric material including, but not limited to aluminum nitride, silicon dioxide, aluminum oxide, or other ceramics. In some embodiments, the window 104 may comprise a dielectric material having a dielectric constant of less than 10. In some embodiments, the window may be 20 mm thick, or between 20 mm and 25 mm thick.

In any case, to contain the plasma in the plasma volume 118, a collar assembly 116 may define an aperture that acts as a sidewall and partially defines the plasma volume 118. The collar assembly 116 may have any thickness that is suitable for containing plasma within the plasma volume 118 and that does not interfere with the electric field produced by the coil 108. In an exemplary embodiment, the collar assembly 116 has a thickness in a range of from 4 mm to 6 mm. In another exemplary embodiment, the collar assembly 116 has a substantially uniform thickness (e.g., ±0.5 mm) along its entire axial length. In still another embodiment, the collar assembly 116 has a varying thickness along its axial length. In some embodiments the aperture of the collar assembly may have a diameter of 370 mm. In some embodiments, the aperture of the collar assembly may have a diameter of between 350 mm and 400 mm.

In some embodiments the collar assembly 116 may include an annular structure 121. The annular structure may secure the window 104 during operation of the plasma generator system along with an O-ring 132. In some embodiments the annular structure may be a continuous ring having an inner diameter of 390 mm. In some embodiments, the annular structure may have an inner diameter of between 380 mm and 400 mm. As will be discussed further below, in some embodiments the annular structure may non-circumferentially continuous, comprising one or more gaps.

To provide an electric field within the plasma volume 118, one or more coils 108 are located above the window 104. In an exemplary embodiment, the coils 108 are made of a conductive material, such as copper or a copper alloy, and each coil may have a first end and a second end. The first end may be electrically coupled to the energy source 110, while the second end may be electrically coupled to an electrical ground. In some embodiments, the one or more coils 108 may be 3 mm above the window 104, or between 2 mm and 4 mm above the window 104. This may allow cooling gas, e.g., air, to flow below and around the coils 108.

In some embodiments, the coils 108 may be sized so as to fit within, or be inscribed in, an annular area have an inner diameter and an outer diameter. In some embodiments, the inner diameter of the coils is 170 mm (i.e., the diameter of a circle circumscribed by the coils 108). In some embodiments, the inner diameter of the coils is between 160 mm and 180 mm. The inner diameter may be defined to allow space for a gas flow distributor 106 and cooling structures 109. Gas flow distributor 106 may extend through the window 104 and flow process gas into the plasma volume, while cooling structures 109 may flow a cooling gas 127 downwards against the window 104; the cooling gas 127 may then flow across the window 104 and coils 108 to cool the coils 108 and/or the window 104 during operation of the system.

Conversely, as will be discussed further below, the outer diameter of the coils 108 may be limited to reduce capacitive coupling between the coils 108 and the annular structure 121 or collar assembly 116. In some embodiments, the outer diameter of the coils is 300 mm (i.e., the diameter of a circle circumscribing the coils 108). In some embodiments, the outer diameter of the coils is between 290 mm and 310 mm.

In some embodiments a housing 101 covers the one or more coils and other components that may be located above the window 104. In some embodiments, the housing 101 may be mechanically coupled to the annular structure by various fasteners. In some embodiments, the housing may be part of the annular structure, e.g., the housing is welded to the annular structure or both elements are fabricated as one piece. In some embodiments, the housing 101 is coupled to the collar assembly via the annular structure 121. The housing 101, along with the window 104, may define an interior volume, wherein the one or more coils as well as various other components, such as valves and piping for process gases, may be located within the interior volume.

To control a manner in which the energy source 110 operates, the controller 111 is operatively coupled thereto. The controller 111 may be an analog controller, a discrete logic controller, a programmable array controller (PAL), a programmable logic controller (PLC), a microprocessor, a computer or any other device capable of carrying out the sequence of events outlined in method 700 described below. In one exemplary embodiment, the controller 111 determines a magnitude of power to be supplied to the one or more coils 108 and provides commands to the energy source 110. In addition to controlling the energy source 110, the controller 111 may also be operatively coupled to a processing gas source 177 and may provide commands thereto to supply an amount of processing gas to the plasma volume 118. While the controller 111, gas source 177, and energy source 110 are shown within the housing 101, it should be understood that these components may be located outside of the housing and connected to components inside the housing (e.g., the coils 108 or gas flow distributor 106).

Processing gas source 177 may include one or more gas sources and a corresponding one or more valves or other flow control components (e.g., a mass flow controller or liquid flow controller). Controller 111 may be connected to the one or more valves or other flow control components to cause them to switch states and thereby allow different gases or a combination of gasses to be flowed at different times and/or flow rates. In some embodiments a the one or more gas sources may fluidically connected to a mixing vessel for blending and/or conditioning process gases prior to delivery to gas flow distributor 106

The energy source 110 may be a radio frequency (RF) energy source or other source of energy capable of supplying power to and energizing the coil 108 to form an electric field. In an exemplary embodiment, the energy source 110 includes an RF generator that is selected for an ability to operate at a desired frequency and to supply a signal to the coil 108. For example, the RF generator may be selected to operate within a frequency range of 0.2 MHz to 20.0 MHz. In one exemplary embodiment, the RF generator may operate at 13.56 MHz. In an exemplary embodiment, the energy source 110 may include a matching network disposed between the RF generator and the coil 108. The matching network may be an impedance matching network that is configured to match an impedance of the RF generator to an impedance of the coil 108. In this regard, the matching network may be made up of a combination of components, such as a phase angle detector and a control motor; however, in other embodiments, it will be appreciated that other components may be included as well.

The processing gas may be diffused within the gas flow distributor 106 before being injected into the plasma volume 118. In this way, the gas may be substantially uniformly distributed into the plasma volume 118. In some embodiments the window 104 may include an inlet 148 to the plasma volume 118 that allows gas to flow into the plasma volume 118. In some embodiments, a gas flow distributor 106 is disposed in the plasma volume inlet 148. According to one exemplary embodiment, the gas flow distributor 106 is made of a material that is non-conductive and is capable of withstanding corrosion when exposed to the processing gas. Suitable materials include, for example, dielectric materials such as silicon dioxide.

With continued reference to FIG. 1, when the energy source 110 energizes the coils 108, an electric field is formed in a selected portion of the plasma volume 118, thereby ionizing the processing gas that may flow therethrough to form ionized gas. As used herein, the term “ionized gas” may include, but is not limited to, charged particles, ions, electrons, neutral species, excited species, reactive radicals, dissociated radicals, and any other species that may be produced when the processing gas flows through the electric field. To control dispersion of the ionized gas across the work piece 102, the showerhead 112 may be positioned between the plasma volume and the workpiece. In one exemplary embodiment, the showerhead 112 may be made from any suitable material that is relatively inert with respect to the plasma, such as aluminum nitride, alumina, or other ceramics. Generally, the showerhead is sized to distribute gas over an entirety of the workpiece 102 and thus, has a correspondingly suitable diameter.

The showerhead 112 may have through-holes to allow gas passage therethrough. In particular, the showerhead 112 includes through-holes 186 that are suitably sized and spaced to disperse the ionized gas over the work piece 102 in a substantially uniform manner. In one exemplary embodiment, the through-holes 186 have a diameter in a range of from 2 mm to 10 mm. Additionally, the through-holes 186 are disposed in a substantially uniform pattern on the showerhead 112 in one exemplary embodiment but, in another exemplary embodiment, the through-holes 186 are disposed in a non-uniform pattern, e.g., a center-focused hole distribution or an edge-focused hole distribution.

In an exemplary embodiment of the present invention, the showerhead 112 may be directly coupled to the collar assembly 116, as shown in FIG. 1. For example, the showerhead 112 may be coupled to the collar assembly 116 via bolts, clamps, adhesives or other fastening mechanisms. In another embodiment, the showerhead 112 may be integral with the collar assembly 116.

It will be appreciated that, although FIG. 1 illustrates an embodiment of the plasma generator system 100 including certain components, additional components or components shaped differently than those shown in FIG. 1 may alternatively be employed.

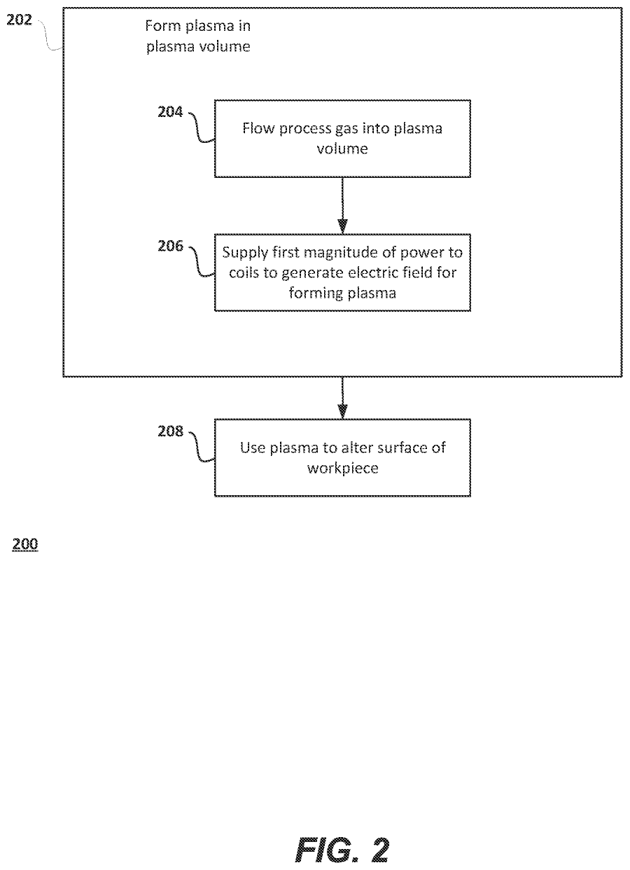

FIG. 2 presents a flow diagram of a method 200 of forming plasma, according to an exemplary embodiment, that may be used with system 100 and a controller, such as controller 111, and may be adapted to cause the system 100 to perform one or more steps of method 700. For example, the controller may be adapted to provide commands to an energy source, such as energy source 110, to perform the various steps below, and/or the controller may be adapted to provide commands to a processing gas source, such as processing gas source 177, to perform one or more of the various steps below. In an exemplary embodiment, a first plasma is formed within a plasma volume, step 202.

In some embodiments, step 202 may include flowing a process gas into the plasma volume, step 204, before, after, or concurrent with forming an electric field, step 206. The process gas may be injected into the plasma volume through inlet 148 and/or gas flow distributor 106. In some embodiments the gas flow distributor may have a plurality of openings to distribute process gas throughout the plasma volume.

The particular gas selected as the processing gas may depend on the particular process in which the plasma may be used. In an exemplary embodiment, the processing gas includes a fluorine-comprising gas. Examples of fluorine-comprising gases suitable for use include nitrogen trifluoride (NF₃), sulfur hexafluoride (SF₆), hexafluoroethane (C₂F₆), tetrafluoromethane (CF₄), trifluoromethane (CHF₃), difluoromethane (CH₂F₂), octofluoropropane (C₃F₈), octofluorocyclobutane (C₄F₈), octofluoro[1-]butane (C₄F₈), octofluoro[2-]butane (C₄F₈), octofluoroisobutylene (C₄F₈), fluorine (F₂), and the like. In another embodiment, the processing gas may comprise a hydrogen-containing gas, such as H₂. In another embodiment, the processing gas may comprise an oxygen-comprising gas. For example, the oxygen-comprising gas may include, but is not limited to, oxygen (O₂) and N₂O. In other embodiments, the processing gas may additionally comprise an inert gas, such as, for example, nitrogen (N₂), helium, argon, and the like. In other embodiments, different gases and different ratios may be used. In some embodiments, process gases may be flowed without an inert gas, e.g., without flowing helium gas.

In some embodiments, method 200 may be performed at vacuum pressure. In some embodiments, the pressure may be between 0.5 torr and 10 torr, or between 1 torr and 3 torr.

In accordance with another exemplary embodiment, step 202 may further include forming an electric field in the plasma volume to form the first plasma, step 206. During operation of the plasma generator system 100, energy source 110 is connected to each coil and provides power to the coils to form an electric field. In accordance with an exemplary embodiment of the present invention, step 206 may include supplying a first magnitude of power to coils of the system to form the electric field. In an embodiment, the first magnitude of power is a magnitude that is sufficient to cause the system to operate in an inductive mode into which the system transitions from an initial capacitive mode. In this way, the first magnitude of power may be a value in a range having a lower limit, where the lower limit is a power magnitude that is suitable for transitioning the system from the capacitive mode to the inductive mode.

During operation, two different electric field configurations are created, namely, a capacitively-coupled electric field (capacitive component) and an inductively-coupled electric field (inductive component). The capacitively-coupled electric field is defined by electric field lines that extend between adjacent turns of the coil and have components that are normal to the surface of the window. The inductively-coupled electric field is created when the current in the coil creates an RF magnetic field which penetrates the window and induces an electric field as described by Faraday's Law. The inductively-coupled electric field has electric field lines that typically have no component normal to the surface of the chamber.

When the system is powered on and power is initially supplied to the coil, the relative strength of the electric field of the capacitive component is greater than that of the inductive component. In such cases, the system is in a “capacitive mode”. As the power is increased, the strength of the inductively-coupled electric field increases, as the relative strength of the capacitively-coupled electric field decreases. This may result from an increase of power absorbed by the plasma, resulting in an increase in the number of charged particles to increase a magnitude of current in the coil and in a larger percentage of power coupled into the inductive component. At a certain power level, the system may experience a mode transition (also known in the art as a “mode jump”), where a rapid increase in the inductive component along with an associated rapid decrease in the capacitive component may occur. In such case, the system is in an “inductive mode”.

A particular magnitude of power suitable for transitioning from the capacitive mode into the inductive mode may depend on system designs. Specifically, the particular current, voltage, and power required to create the capacitive and/or inductive mode depends largely on the configuration and dimensions of the window, plasma volume, and the coil, the process chemistry, and process parameters.

In accordance with an exemplary embodiment, the system may be configured similar to FIG. 1. In such case, the system may be designed such that the first magnitude of power has a lower limit of 600 watts or 1000 watts, which may be employed to transition the system from a capacitive mode to an inductive mode.

After a first plasma is formed, it may be used in various processes in which plasma may be employed to alter a surface of a workpiece, step 208. In accordance with an exemplary embodiment, a continuous supply of the processing gas may be fed into the plasma volume and allowed to circulate with the first plasma and through the electric field, and RF current is continuously supplied to the coil such that the inductive mode produces an RF electric field within the chamber. As the processing gas circulates, charged particles making up the plasma are accelerated within the plasma volume causing at least a portion of the processing gas to dissociate into reactive radicals, which may be flowed to a workpiece disposed below the showerhead of the plasma volume. For example, in an embodiment in which the processing gas includes a fluorine-comprising gas, a portion of the fluorine-comprising gas ionizes to form electrons, fluorine ions and reactive fluorine radicals. In an exemplary embodiment of the present invention, some of the reactive fluorine radicals may flow from the plasma volume, through a showerhead, and may deposit on the workpiece, while another portion of the reactive fluorine radicals may recirculate within the plasma volume before depositing onto the workpiece. After the workpiece is processed, it may be moved to another portion of the system.

As noted above, in various embodiments a process gas used during the process of FIG. 2 may include an inert gas, such as helium. Helium may act to stabilize a plasma by being an electron-donor gas (i.e., a species having a low ionization energy). In some embodiments, helium may not be part of the process gas. In such embodiments, a plasma may have increased etching properties, particularly for a plasma formed from a process gas comprising H₂ or NF₃. In such embodiments, the window 104 may be subject to additional corrosion from the plasma compared to a plasma from a process gas comprising helium, reducing the lifetime of the window 104. In some embodiments, the window 104 comprises a material that is resistant to corrosion by an H₂ or NF₃ plasma while also being transmissive to RF energy, such as aluminum nitride.

Furthermore, in various embodiments method 200 may be implemented where an RF generator operates at a high power, e.g., 3000 W or greater. In some embodiments, high power operations increase the temperature of the window facing the plasma volume, causing a more pronounced thermal gradient in the window 104 between a side facing the plasma and an opposite side being cooled by the cooling structures 109. In some embodiments, the window 104 comprises a material that has a high thermal conductivity to reduce the risk of thermal stress cracks in the window 104 resulting from thermal stresses across the window 104 arising from uneven heating of the window 104. For example, the window 104 may comprise a thermally conductive material that has a temperature of less than 200° C. while operating method 2 at an RF power of 3000W. In some embodiments, the thermally conductive material may comprise aluminum nitride.

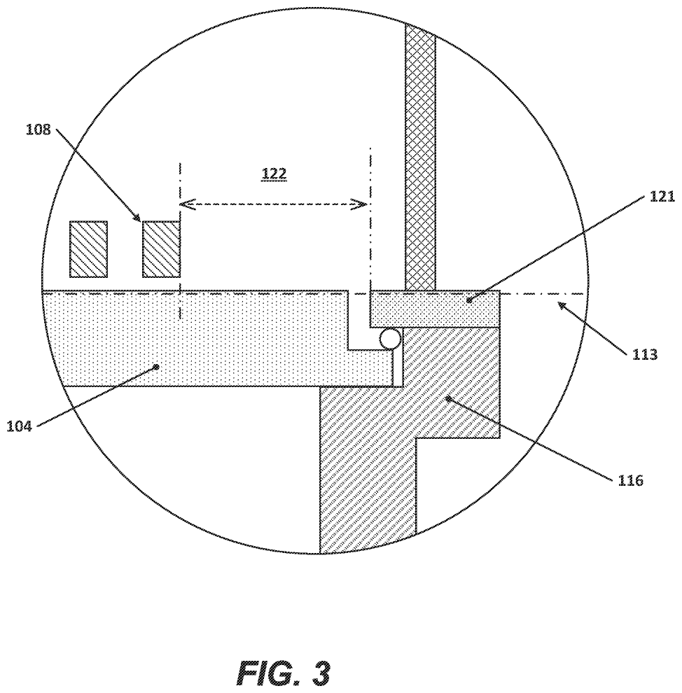

As noted above, the configuration and dimensions of the coils may affect the power required to cause the system to transition between capacitive and inductive modes. FIG. 3 presents an enlarged view of a portion of FIG. 1. During operation of the plasma generator system 100 power is provided to the coils to form an electric field, and the first magnitude of power to cause a mode jump may be governed, at least in part, by the configuration of the coils. In some embodiments, particularly those using a pure H₂ process gas or a process gas without helium, the first magnitude power would increase, e.g., to 1000W or more, which is undesirable as operating at a higher power increases wear on various components and thus reduces the lifetime of components, reducing the efficiency of the plasma generator system; it also is more costly due to the increased power consumption. The inventors tested multiple coil designs to improve the efficiency of the plasma generator system, in particular to lower the power threshold required to mode jump in such systems. Typically, increasing the number of coils increases the inductance generated by the coils, which decreases the lower limit of the first magnitude power, i.e. the threshold power to transition the system from a capacitive mode to an inductive mode. Furthermore, reducing the spacing between coils may also increase inductance and thus reduce the first magnitude power. However, there is a lower limit to such spacing, as arcing may occur between the coils, shorting them, or stray capacitance may inhibit the inductance caused by the coils, increasing the power required to cause a mode jump.

However, when the present inventors, in the context of a system such as that shown in the example of FIG. 1, increased the number of coils to, e.g., 6 total turns, the mode jump required additional power. Furthermore, when the inventors increased the spacing between coils, to reduce inter-coil coupling, the mode jump power threshold still did not decrease and sometimes increased. Instead, the inventors determined that decreasing the number of coils and/or decreasing the outer diameter of the coils reduced the transition power threshold.

Without being bound by theory, during operation the coils may inductively couple with the annular structure and/or the collar assembly, producing eddy currents that divert electrical power that would otherwise be used for plasma generation. Additional power is required to offset the eddy current loss and achieve a desired amount of power delivery to the plasma, increasing the RF power threshold to mode jump. As noted above, the inner diameter of the coils 108 may be limited by components located near the center of the system 100, e.g., the gas flow distributor 106 or the cooling structures 109. Thus, increasing the number of coils or the spacing between coils (while keeping the coil width/thickness the same) may reduce a radial distance 122 between the coils 108 and the annular structure 113 or collar assembly 116 (which may typically comprise conductive metals such as aluminum). The reduced radial distance increases eddy current formation in one or both of those elements, increasing RF power requirements to cause a mode jump. Furthermore, in some embodiments eddy currents are lesser (or have a lower impact) in the part of the collar assembly 116 that is below the window 104. Thus, while some portions of the collar assembly 116 may be closer to the coils 108 than any portion of the annular structure 121, increasing the distance between the annular structure 121 (or any element that is above the first side 156 of the window 104) and the coils 108 may significantly reduce the RF power threshold to transition the plasma from capacitive mode to inductive mode.

Thus, in some embodiments the radial distance 122 is between the coils 108 and the interior edge of the annular structure 121 (as illustrated by the dashed lines). In some embodiments, radial distance 122 is a radial distance between an outermost portion 144 of the one or more coils 108 (as indicated by a dashed circle circumscribing coils 108) and an innermost portion 146 of an electrically conductive portion of the collar assembly 116 (including annular structure 121 and illustrated by a dashed line) that intersects a reference plane 113 that is above the first side 156 of the window 104, or between the first side of the window 104 and the coils 108. Returning to FIG. 3, reference plane 113 is coincident with the top surface of annular structure 121 and the second side 157 of the window 104, but in other embodiments the top surface of annular structure 121 may be above or below the second side 157 of the window 104. In some embodiments, the reference plane 113 is above the first side of the window 104. In some embodiments, reference plane 113 may be perpendicular to a first axis 114 that is perpendicular to the top surface of the window 104. In some embodiments, radial distance 122 is measured along a line that intersects the first axis 114 and/or is coincident with reference plane 113.

In various embodiments radial distance 122 may be at least 40 mm, at least 50 mm, at least 60 mm, between 40 mm and 60 mm, or 60 mm. Generally, the smaller the outer diameter of the coils 108, the larger the radial distance 122.

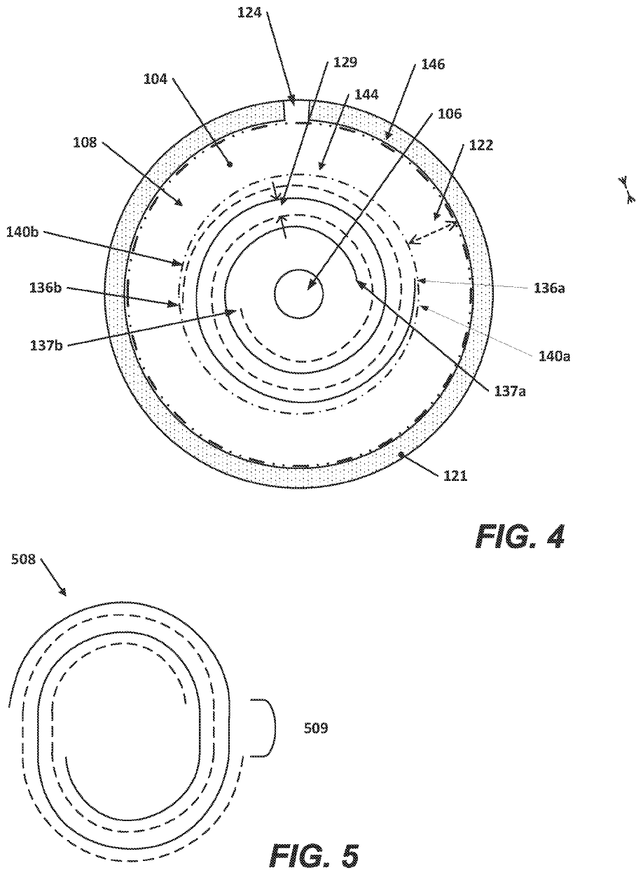

FIG. 4 presents a top down view of plasma generator system 100. As noted above in respect to FIG. 3, there is a radial distance 122 between an outermost portion of the coils 108 and the annular structure 121. In some embodiments, to reduce the formation of eddy currents in the annular structure, the annular structure may be a non-continuous ring. In some embodiments one or more gaps 124 are present in the annular structure 121. While FIG. 4 shows one gap, more than one gap may be present. In some embodiments multiple gaps may be spaced evenly around the circumference of annular structure 121. Gaps may reduce eddy current formation by inhibiting the flow of electric current around the annular structure. In some embodiments, the gaps are in an electrically conductive portion of the annular structure. In some embodiments, the gaps may be air, while in other embodiments the gaps may be an electrical gap, e.g., filled with a plastic insulator or dielectric that inhibits current flow. In some embodiments the housing 101 may have similar gaps, i.e., air gaps or electrical gaps, as the annular structure.

As noted above, one or more coils 108 are located above the window 104, and may be energized to form an electric field. In the embodiment of FIG. 4 there is a first coil 140a and a second coil 140b, however more or fewer coils may be present in various embodiments. Each coil may have a first end 136a and 136b and a second end 137a and 137b. The first ends 136a-b may be electrically coupled to the energy source 110. The second ends 137a-b may be electrically coupled to an electrical ground, terminating the coil. It should be understood that other configurations of connections are within the scope of this disclosure.

Each coil loops around a central axis (such as axis 114 shown in FIG. 1). Each substantially complete loop (although with the ends of the loop separated by a radial gap) about the central axis by a coil may be considered a turn. Thus, in the example of FIG. 4, each of coils 136a and 136b has two turns. In various embodiments the total turns by the one or more coils may include summing the turns of each coil (thus, in FIG. 4 the coils 108 may have 4 total turns). While the coils shown in FIG. 4 are substantially symmetrical about the central axis, in other embodiments they may be non-symmetric. For example, in embodiments implementing multiple coils, a first coil may have greater or fewer turns than a second coil, e.g., the total turns may be an odd number (e.g., a first coil having 1 turn and a second coil having 2 turns may have a total turns of 3). In some embodiments a coil may have a substantially spiral shape, such as those shown in FIG. 4.

In various embodiments there is an inter-coil spacing 129 between the wires of the coil. If the turns of the coil are too close together, arcing or stray capacitance between the coils may occur that shorts the coils or otherwise reduces the inductance generated by the coils. A minimum inter-coil spacing may inhibit these effects, and such inter-coil spacing may depend on the frequency of the RF source connected to the coils. In some embodiments, the inter-coil spacing is at least 6 mm.

In some embodiments, a portion of a coil may follow a path that does not follow a spiral, e.g., arcuate portions with intervening straight portions. FIG. 5 presents coils 508 having straight portions 509. In such embodiments there may be multiple straight portions, each straight portion occurring at a 180 degree rotation from another straight portion. In some embodiments the coils may not have a spiral shape. In some embodiments using multiple coils, one coil may be an “inner coil,” having a smaller outer diameter than an inner diameter of an “outer coil,” such that the inner coil is closer to the central axis than the outer coil. Furthermore, in some embodiments each coil may not complete a complete rotation, or turn. For example, two coils may each complete 1.5 rotations, having 1.5 turns each and 3 total turns. Other embodiments are within the scope of this disclosure. As noted above, there may be one or more coils, e.g., 2 coils or 3 coils.

As noted above, in some implementations a controller 111 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 111, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

### Conclusion

System and methods have now been provided that provide improved plasma generation capabilities over conventional systems. The above-described plasma generator systems experience a reduced downtime between plasma generation processes as compared to conventional systems, and they do so while reducing exposure of surrounding system components to high amounts of power. As a result, the improved plasma generator systems now include components, such as RF components, gas flow distributors and tubes, having improved useful lives compared to components of conventional plasma generator systems. Additionally, maintenance costs of the systems are reduced as well.

Various modifications to the implementations described in this disclosure may be readily apparent to those skilled in the art, and the generic principles defined herein may be applied to other implementations without departing from the spirit or scope of this disclosure. Thus, the claims are not intended to be limited to the implementations shown herein, but are to be accorded the widest scope consistent with this disclosure, the principles and the novel features disclosed herein.

Certain features that are described in this specification in the context of separate implementations also can be implemented in combination in a single implementation. Conversely, various features that are described in the context of a single implementation also can be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Further, the drawings may schematically depict one more example processes in the form of a flow diagram. However, other operations that are not depicted can be incorporated in the example processes that are schematically illustrated. For example, one or more additional operations can be performed before, after, simultaneously, or between any of the illustrated operations. In certain circumstances, multitasking and parallel processing may be advantageous. Moreover, the separation of various system components in the implementations described above should not be understood as requiring such separation in all implementations, and it should be understood that the described program components and systems can generally be integrated together in a single software product or packaged into multiple software products. Additionally, other implementations are within the scope of the following claims. In some cases, the actions recited in the claims can be performed in a different order and still achieve desirable results.

1. An apparatus, comprising:
a process chamber, wherein the process chamber comprises:
a window, wherein the window comprises a dielectric material that is transmissive to radio frequency (RF) energy, wherein the window has a first side and a second side opposite the first side;
a collar assembly having an aperture covered by the window, wherein the collar assembly supports the first side of the window; and
one or more RF coils positioned above the second side of the window, wherein, when viewed along a first axis perpendicular to the window, a radial distance between an outermost portion of the one or more RF coils and an innermost portion of an electrically conductive portion of the collar assembly that intersects with a first reference plane that is perpendicular to the first axis and between the first side of the window and the one or more RF coils is greater than or equal to 40 mm.

2. The apparatus of claim 1, wherein the one or more coils comprise 4 or fewer total turns.

3. The apparatus of claim 1, wherein the one or more coils comprise 3 or fewer total turns.

4. The apparatus of claim 1, wherein the diameter of the flat window is less than 350 mm.

5. The apparatus of claim 1, further comprising a housing that is mechanically coupled to the collar assembly, wherein the one or more RF coils are within an interior volume of the housing.

6. The apparatus of claim 1, wherein the collar assembly includes an annular structure that includes one or more gaps.

7. The apparatus of claim 6, wherein the one or more gaps comprise air.

8. The apparatus of claim 6, wherein the one or more gaps comprise a dielectric material.

9. The apparatus of claim 1, further comprising one or more cooling structures that direct air towards the flat window.

10. The apparatus of claim 1, wherein the window has a thickness of between 20 mm and 25 mm.

11. The apparatus of claim 1, wherein the aperture has a diameter of between 350 mm and 400 mm.

12. The apparatus of claim 1, wherein the dielectric material has a dielectric constant less than 10.

13. The apparatus of claim 1, wherein the dielectric material is aluminum nitride, aluminum oxide, or both.

14. The apparatus of claim 1, wherein the process chamber further comprises a showerhead positioned below the window.

15. The apparatus of claim 1, wherein the process chamber further comprises a pedestal configured to support a substrate.

16. The apparatus of claims 1, further comprising one or more processors and one or more memories connected to the one or more processors, the one or more memories storing computer-executable instructions that, when executed by the one or more processors, control the one or more processors to:
cause a first process gas comprising hydrogen gas to be flowed into a plasma volume below the window; and
cause a plasma to be ignited using the first process gas, wherein the plasma is generated by providing power to the one or more RF coils.

17. The apparatus of claim 16, wherein the computer-executable instructions that, when executed by the one or more processors, control the one or more processors to cause the first process gas to be flowed into the plasma volume cause the first process gas to be flowed into the plasma volume without an accompanying flow of helium.

18. The apparatus of claim 16, wherein the plasma is an inductively coupled plasma.

19. The apparatus of claim 18, wherein the one or more memories store further computer-executable instructions that, when executed by the one or more processors, control the one or more processors to cause the plasma to transition to an inductively coupled plasma at a power of the one or more RF coils of less than 1000W.

20. The apparatus of claim 16, wherein the one or more memories store further computer-executable instructions that, when executed by the one or more processors, control the one or more processors to cause the process chamber to maintain a pressure of the plasma volume greater than 1 Torr.

21. The apparatus of claim 16, wherein the one or more memories store further computer-executable instructions that, when executed by the one or more processors, control the one or more processors to cause the process chamber to maintain a pressure of the plasma volume between 1 Torr and 3 Torr.
